(19) United States
(12) Patent Application Publication
(10) Pub. No.: US 2008/0073743 A1
(43) Pub. Date: Mar. 27, 2008

(54) Templated growth of semiconductor nanostructures, related devices and methods

(75) Inventors: Azar Alizadeh, Wilton, NY (US); Fred Sharifi, Niskayuna, NY (US); Christopher Fred Keimel, Schenectady, NY (US); Ji Ung Lee, Niskayuna, NY (US); Nicole Andrea Evers, Niskayuna, NY (US); Kenneth Roger Conway, Clifton Park, NY (US); Edit Libia Braunstein, Orlando, FL (US); Colin Elliott Jones, Santa Barbara, CA (US)

Correspondence Address: BUCHANAN, INGERSOLL & ROONEY PC, POST OFFICE BOX 1404, ALEXANDRIA, VA, 22313-1404, US

(73) Assignee: LOCKHEED MARTIN CORPORATION, Bethesda, MD (US)

(21) Appl. No.: 11/707,935

(22) Filed: Feb. 20, 2007

Related U.S. Application Data
(60) Provisional application No. 60/774,219, filed on Feb. 17, 2006.

(51) Int. Cl. H01L 31/06; H01L 21/00

(52) U.S. Cl. 257/461; 438/93; 257/E31.08; 257/E21.001; 977/954

(57) ABSTRACT

Photodetector arrangements, designs and fabrication techniques are described related to semiconductor nanostructures. Arrangements and techniques are described which utilize a nano-patterned template for growing semiconductor nanostructures and/or heterostructures. Resulting photodetectors are also described.

The present application claims priority pursuant to 35 U.S.C. §119 to U.S. Provisional Patent Application Ser. No. 60/774,219 filed Feb. 17, 2006.

### FIELD OF THE DISCLOSURE

The present disclosure relates to arrangements, compositions, as well as design and fabrication techniques relating to quantum dots. The present disclosure also relates to photodetectors and methods of making and using the same.

### BACKGROUND

In the discussion of the state of the art that follows, reference is made to certain structures and/or methods. However, the following references should not be construed as an admission that these structures and/or methods constitute prior art. Applicant expressly reserves the right to demonstrate that such structures and/or methods do not qualify as prior art.

In semiconductor devices, such as photodetectors, the electrical output signal is often a result of the change in the electronic energy distribution upon radiation absorption. Photodetectors can be classified according to their frequency range of operation. In particular, infra red photo detectors (IRPDs) operate in the frequency range 0.7 to beyond 20 microns including near infra red (NIR; 0-1.4 microns), short wave infra red (SWIR; 1.4-3.0 microns), mid-wave infra red (MWIR; 3.0-8.0 microns), long-wave infra red (LWIR; 8.0-12.0 microns), and very long-wave infra red (VLIWIR; 8.0-20.0 microns and beyond).

IRPDs are of particular interest in a variety of applications. The most common IRPD fabrication technologies include indium antimonide (InSb) based-photodiodes, mercury cadmium telluride (HgCdTe) based photodiodes and, gallium arsenide/aluminum gallium arsenide (GaAs/AlGaAs) multi quantum well heterojunctions. In order to achieve a high signal-to-noise performance and a very the Stranski-Krastanow process a thin semiconductor layer is epitaxially grown on a semiconductor substrate with a slightly different lattice constant. The magnitude of lattice mismatch is typically between 1.8 and 10%. During the early stages of growth, a thin layer of strained semiconductor film is first deposited that follows the substrate lattice. At later stages of growth, and while the film thickness becomes thicker, a transition in the growth mechanism from 2-dimensional to 3-dimensional growth takes places and the semiconductor epilayer relieves the lattice mismatch induced strain by forming pyramidal or lens shaped quantum dot structures. The dimension of these dots at their base is between 10-30 nm and their height is between 5-10 nm. The dots have quantized energy levels that can absorb light to an excited state and then free a carrier to the surrounding capping material.

The Stranski-Krastanow grown quantum dots suffer from non-uniformity in their size and shape, which has a deleterious impact in the functioning of the IRPD. More importantly, in Stranski-Krastanow growth processes, 3 dimensional growth of quantum dot “islands” is preceded by initial 2 dimensional growth on a wetting layer. Therefore, as schematically illustrated in FIG. 1, within each layer of the IRPD, all the quantum dots 110 are connected via the wetting layer 120 which overlaps a substrate 130. The wetting layer 120 can increase the dark current, which increases the noise. Current self-assembled technology does not promote densely packed quantum dots, therefore much of the surface area is not utilized for detection purposes.

Semiconductor nanostructures have the potential to revolutionize a variety of technologies such as optoelectronics, field emission and high temperature sensing. However, current quantum dot growth techniques have only limited control over the dot density, dot width, dot height and the wetting layer.

### SUMMARY

According to certain aspects of the present invention, a selective area or templated growth method is utilized to provide tailored and highly confined semiconductor nanostructures. Templated growth of semiconductor nanostructures, which involves epitaxial growth through a selective mask, allows for precise control fast response, the above-mentioned IRPDs often require cryogenic cooling that reduces the dark leakage current. For many of the applications cited previously, it is highly desirable to develop highly sensitive and fast response un-cooled or slightly cooled focal plane array photodetector with detectivities (D*) greater than D*>10⁹ cm-Hz^{1/2}/W.

IRPDs based on microbolometers can operate at or near room temperature. They are made with many materials including amorphous silicon, YCuBaO, and vanadium oxide. However, these photo detectors lack the fast response required for many applications. In addition, microbolometers often require complex and costly manufacturing processes for their integration in a focal plane array configuration.

Recently, IRPDs having active elements based on intersubband transitions in low dimensional systems, such as quantum dots, have been proposed to satisfy a high-temperature, high-speed detector need. Three dimensionally confined quantum dots have a large relaxation time for the excited states (on the order of nanoseconds) due to a phonon bottleneck. There is only a small density of phonons available with the needed energy and momentum needed to return the excited electron to the ground state. Consequently, the photo-excited carriers can be moved to the surrounding GaAs layer through tunneling or thermalization processes and collected as photocurrent before returning to the ground state. In these highly confined systems, lower dark currents, and thus higher operating temperatures have been reported. The lower value of dark current in the quantum dot based IRPDs has been mainly associated with electron wave function confinement, which results in equivalent photoionization and thermionic emission energies for electrons captured in the quantum dot. The electrons in the quantum dots are excited by the incident IR radiation before they can be thermally excited out of the quantum dot. Another reported advantage of quantum dot based photodetector active elements is their sensitivity to normal incidence radiation which results in higher quantum efficiency and simpler optical configurations than for quantum well detectors.

In current IRPD active elements, low dimensional quantum dots are fabricated through random self-assembly processes such as Stranski-Krastanow. In over quantum dot size, shape, spacing and uniformity, and could mitigate the nonradiative defects associated with direct writing techniques. The patterned growth technology in this disclosure allows increases in the dot densities of 10 to 100 fold over self assembly methods. This is advantageous in applications such as optical detectors where an increase in dot density results in a larger fraction of incident light being absorbed within each layer. Therefore, in comparison with the conventional Stranski-Krastanow method, fewer layers with each layer having a higher a dot density can be utilized in the final device. Patterned growth by allowing separate control over the dot height and width increases the range and ease of tuning the quantum dot properties. Finally, the patterned growth approach proposed here allows for controlled growth of nanostructure dots either on a continuous layer, such as a wetting layer, or in such a way that all the dots are isolated from each other.

Selective growth of semiconductor structures inside windows having dimensions of about 100 nm or less is contemplated by the present invention. An example would be the templated growth of indium arsenide nanostructures inside SiO₂ or Si₃N₄ windows having dimensions of about 20 nm or less, using molecular beam epitaxy (MBE).

Other materials can be grown in the templates including groups II/VI, III/V, V, and mixed alloy semiconductors.

The morphology and optoelectronic properties of structures produced according to the present invention can be characterized by atomic force microscopy (AFM), scanning electron microscopy (SEM), high resolution tunneling electron microscopy (TEM) and cathodoluminescence techniques.

After device fabrication specific device and material characterization can be performed. For IR detectors, the signal, dark current, and noise would be measured as functions of voltage, temperature, and wavelength. The responsivity, resistivity, quantum efficiency, and detectivity (D*) can then be calculated. The material properties of energy levels, dot excitation lifetime, transport properties of mobility and lifetime, surface recombination, and optical absorption can be measured.

To create the template, suitable lithography techniques may be utilized. For example, electron beam writing or block copolymers could be used to create a resist nano-pattern for dry etching templates on a substrata, such as GaAs, InP, or Si. Block copolymers are composed of two or more chemically different polymer chains or blocks joined covalently. Due to chemical incompatibility between the different blocks and the connectivity constraint, block copolymers can spontaneously phase-segregate into well-defined morphologies, such as lamellar, cylindrical, spherical, providing nanometer scale contrast between the different phases. Suitable block copolymer lithography techniques, such as the formation of an ordered nano-porous template preparation through polystyrene (PS)-poly(methyl-methacrylate) (PMMA) lithography, are contemplated. The nanostructured templates are then used to selectively control the MBE growth of heteroepitaxially-grown quantum dots with diameters smaller than about 100 nm, optionally smaller than the excitonic Bohr radius of the semiconductor material, or about 1-40 nm, or optionally less than about 20 nm.

According to the present invention, arrays of semiconductor nanostructures and heterostructures are fabricated through nano-templating and/or nano-patterning. With this approach, the 2 dimensional wetting layer can be eliminated in the templated layer and the quantum dots within this layer will be isolated from each other, i.e., not connected via a wetting layer. Consequently, it is anticipated that the templated growth and nano-patterning approaches provide truly confined zero dimensional nanostructures. This in turn would result in higher detectivities and lower dark currents, and thus higher operating temperatures.

Alternatively, the patterned growth can be used as a seed layer in a multi-layer growth approach such that that the second and/or consecutive layers of dots or nanostructures grow over the initial layer's dots or nanostructures, thereby mimicking the pattern of the first layer due to the strain coupling.

An extension of the seed layer approach is that the seed layer can be any material that can be grown or deposited to create the strain pattern needed to grow associated self-assembled dots in the following layers. This generates multiple layers with high densities of dots for nanostructures by templating only the first “seed” layer, and without the necessity of templating the subsequent layers.

The present invention can provide one or more of the following features and/or advantages:
control over size (length, width and height) and spacing of nanostructures through design and fabrication of a template with nano-pores inside which the nanostructures will be grown;
control over dot densities allowing much higher densities than is possible with self-assembly techniques;
elimination of the wetting layer and thus obtaining zero dimensional systems.
This would decrease the dark current and thus enable operations at higher temperatures;
fabrication of defect free or substantially defect three nanostructures during heteroepitaxial templated growth processes allows for more combinations of substrate-layer/nano-islands and higher values of lattice mismatch;
fabrication of heterostructures in confined geometries;
small detector regions for use with optical concentrators;
improved light absorption with fewer layers of nanostructure arrays with the templated growth process;
growth of thicker nanostructures that are defect free;
fabrication of photodetectors with n-i-n, and p-i-p configurations, where the active layer i consists of a stack of template-grown nanostructures;
control over frequency range of operation by controlling the size of nanostructures inside the active layer; and
use with multi-layer designs to, for example, increase and sharpen absorption, lower dark-currents, or relieve strain.

According to one aspect, the present invention provides a method of making and active element of a photodetector comprising: providing a substrate; providing a template having an opening with its largest dimension no greater than about 100 nm, the opening defining a confined space, locating the template over the substrate; and growing the semiconductor nanostructure within the confined space defined by the opening in the template.

According to another aspect, the present invention provides a photodetector device comprising: a substrate; a first layer comprising an n-doped or p-doped material disposed on the substrate; an active layer disposed on the first layer comprising an array of semiconductor nanostructures having a density of at least about 10¹⁰ nanostructures or dots/cm², optionally with a density of up to about 10¹² nanostructures or dots/cm²; and a second layer disposed on the active layer comprising an n-doped or p-doped material.

According to a further aspect, the present invention provides a photodetector device comprising: a substrate; and an array of semiconductor nanostructures disposed over the substrate, each of the semiconductor nanostructures having a transverse dimension no greater than 20 nm, and the array having a density greater than about 10¹⁰, nanostructures or dots/cm², optionally with a density of up to at least about 10¹² nanostructures or dots/cm², or more.

The term “quantum dot,” as used herein should not be construed as being limited to any particular geometry, unless expressly indicated otherwise.

As used herein, the term “photodetector” means a device that responds in a measurable way to radiant energy. The term encompasses, for example: photoconductive cells, photodiodes, photoresistors, photoswitches, phototransistors, phototubes, and photovoltaic cells.

### BRIEF DESCRIPTION OF THE DRAWING FIGURES

The following detailed description of preferred embodiments can be read in connection with the accompanying drawings in which like numerals designate like elements and in which:

FIG. 1 is a schematic illustration of a self-assembled quantum dot 2-dimensional array constructed according to conventional Stranski-Krastanow techniques.

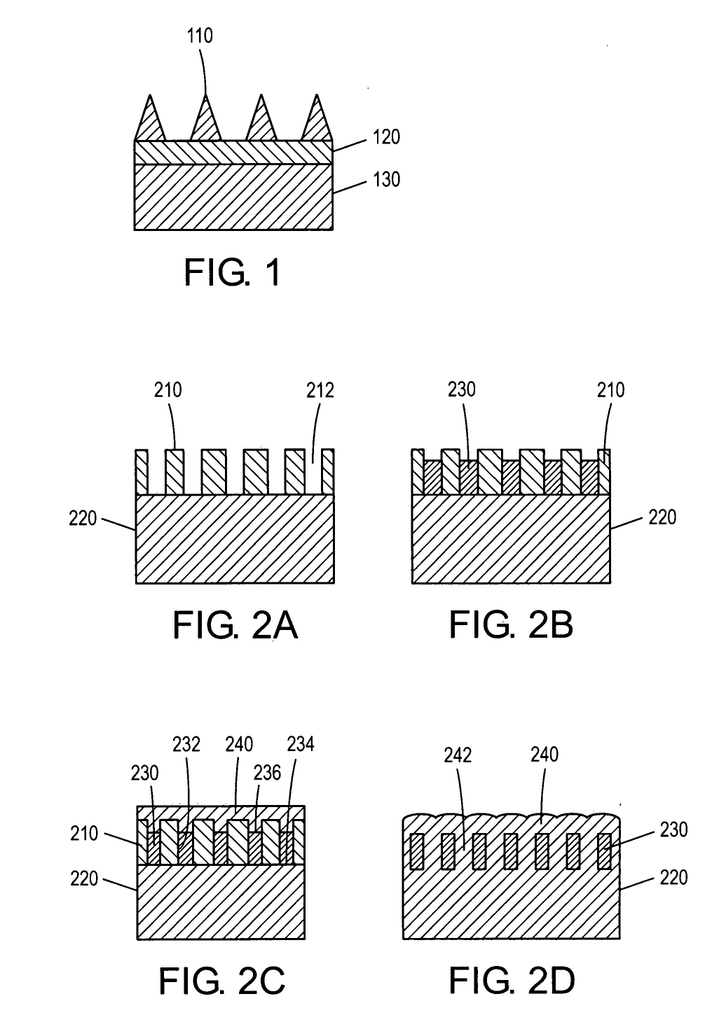

FIG. 2A-2D are schematic illustrations of a fabrication technique performed according to the principles of the present invention.

FIG. 3A-3E are schematic illustrations of another fabrication technique performed according to the principles of the present invention.

FIG. 4A-4B are high-resolution TEM images of quantum dots grown on a substrate according to the principles of the present invention.

FIG. 5 is a schematic illustration of an arrangement comprising multiple layers of semiconductor nanostructures formed according to the principles of the present invention.

FIG. 6A-6B are a schematic illustrations of a photoconductor or photodetector device comprising semiconductor nanostructures formed according to the principles of the present invention, and an array comprising a plurality of such devices, respectively.

FIG. 7A-7F are schematic illustrations of nano-patterning and etching processes performed according to the principles of the presently claimed invention.

FIG. 8A-8D are schematic illustrations of another controlled growth technique for forming nanostructures according to a further embodiment of the present invention.

### DETAILED DESCRIPTION

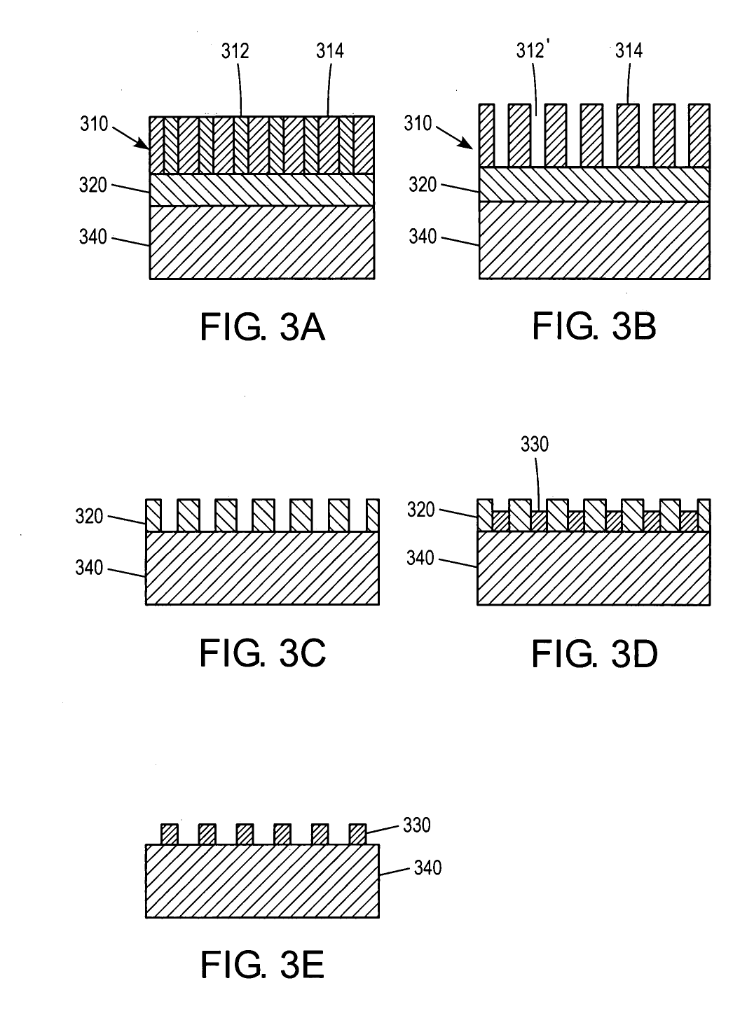

FIG. 2A-2D illustrate nanostructure array fabrication through a nano-templating approach. In step 1, (FIG. 2A) an insulating patterned template 210 with nanopores 212 is formed on a substrate 220. The template 210 is formed from any suitable material, such as SiO₂ or another dielectric material, such as but not limited to Si₃N₄, SiON, SiBON, Al₂O₃, NbOx, etc. The substrate 220 can also be formed from any suitable material, such as GaAs, InP, Si, or Ge The substrate can also comprise a multi-layer structure formed of one or more suitable materials. The patterned template 210 can be formed using suitable techniques such as block copolymer lithography, nano-imprinting, e-beam lithography, extreme UV lithography, interference lithography, soft lithography, anodized alumina templating, and 2-dimensional colloidal crystal lithography, etc.

In step 2 (FIG. 2B) semiconductor nanostructures 230 and heterostructures are grown through the nanometer-dimensioned openings 212 in the template 210 using well-known growth techniques, including, but not limited to, molecular beam epitaxy, metal organic chemical vapor deposition, laser ablation, atomic layer deposition, liquid phase epitaxy, high pressure temperature gradient recrystallization, high pressure solution growth, sublimation, electrochemical deposition and combinations thereof. Different types of semiconductors for example from group III/V, II/VI, V or their alloys can be grown through this templated growth approach.

In one approach one type of nanostructure can be grown inside the holes 212. In another approach, growth conditions can be modified to grow and/or deposit different types of nanostructures including but not limited to Type II super-lattices, quantum wells, barriers, tunnel barrier structures, substrate re-growth, graded layers, resulting in heterostructures inside the confined spaces. Growth conditions also can be adjusted to introduce dopant atoms such as Si. Dimensions of the nanostructures are entirely determined by the size (diameter, width and height) of the opening in the sacrificial template 210 and the growth time, and commonly vary between about 5-100 nm in diameter or transverse dimension and about 5-200 nm in height. Dimensions of the template 210 should be such that the resulting quantum dots are highly confined, for example, smaller than about 100 nm, or smaller than the excitonic Bohr radius of the semiconductor (i.e., about 1-40 nm). Alternatively, the diameter or transverse dimension of the nanostructures were dots can be about 30 nm or less, or optionally about 20 nm or less.

Using techniques such as block copolymer lithography or nano-imprinting, high density arrays of quantum dots or nanostructures having a density greater than about 10¹⁰ dots or nanostructures/cm², or at least about 10¹² dots or nanostructures/cm² or more, can be fabricated over the entire substrate 220. In order to increase the absorption intensity of incident light, ultra high-density arrays of quantum dots are highly desirable.

The template growth process of the present invention allows for fabrication of substantially dislocation free nanostructures of arbitrary heights even when they present a large lattice mismatch with the underlying substrate.

In one embodiment, as illustrated in FIG. 2C, the growth of the nanostructures 230, for example, InAlGaAs quantum dots, is followed by the growth of a capping layer generically illustrated as film 240. The layer 240 may optionally comprise GaAs. In one embodiment, the lateral surfaces 232 of the quantum dots are surrounded by the template 210, while their top 234 and bottom 236 surfaces are in contact with the capping layer 240 and substrate 220, respectively.

In another embodiment, subsequent to the growth of the nanostructures, the template is removed. This can be accomplished by any suitable technique, such as dipping the template, which may be optionally formed from SiO₂, in hydrofluoric acid (HF) or using other well-known wet and/or dry etching techniques. Growth of the capping layer, such as a layer of GaAs, after removal of the template is schematically illustrated in FIG. 2D. As illustrated therein, the capping layer extends into the space 242 previously occupied by the template 210 and thus contacts the lateral surfaces 232 of the quantum dots 230.

In addition embodiments, the semiconductor nanostructure may be capped with a thin layer of higher band gap semiconductor. This capping would allow for passivation of dangling bonds on the nanostructure or quantum dot surface, providing enhanced optical properties. A temporary capping layer may optionally be provided for temporary protection purposes, such as to prevent oxidation. Subsequent to growth and template removal, the temporary capping layer can be removed. Another alternative for additional capping layer could be a thicker material, such as a cladding layer, for device fabrication.

Next, optionally, further annealing of the template-grown nanostructures 230 for surface reconstruction purposes and to alleviate potential damage from etching may be performed. This further annealing may be performed regardless of which of the above-described embodiments are utilized.

In one embodiment, prior to the growth of quantum dots, the template is exposed to one or a combination of processes, such as chemical (wet) etch, high temperature exposure under controlled gas flow and/or low temperature exposure in conjunction with atomic H₂ plasma. These processes can be carried out in the same growth reactor or an auxiliary chamber. These processes are designed to remove potential oxide layers at the nanostructure/substrate growth interface. Removal of this oxide layer facilitates epitaxial growth of high quality defect free crystalline semiconductor nanostructures that are substantially defect free.

In another optional embodiment, subsequent to the cleaning process, an epitaxial buffer layer (such as GaAs or InGaAs) is grown. This growth buffer layer may provide an even more desired growth interface for the epitaxial growth of high quality crystalline active nanostructures such as quantum dots. High quality crystalline nanostructures or quantum dots can yield superior optoelectronic properties, such as enhanced light absorption and/or emission.

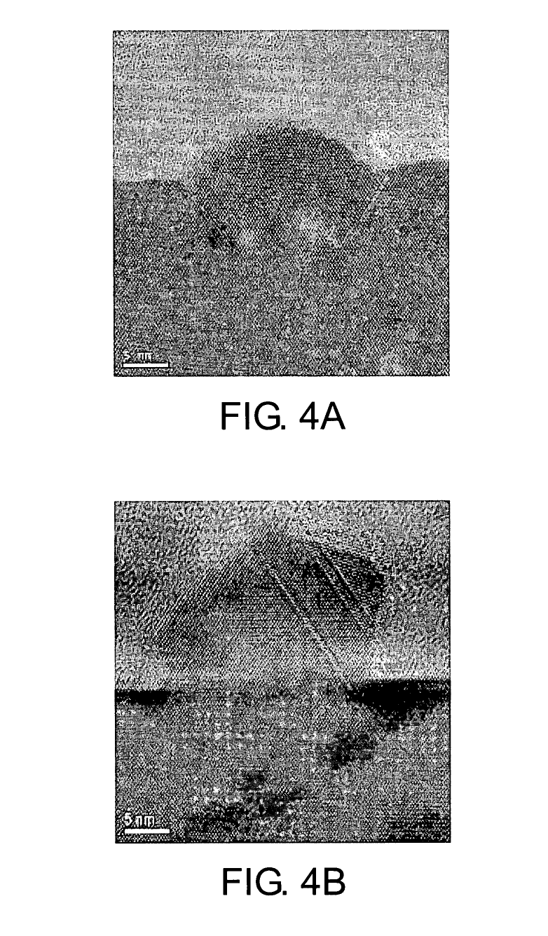

According to an alternative embodiment of the present invention, a fabrication technique, as illustrated in FIG. 3A-3E can be utilized. In the step illustrated in FIG. 3A, a layer of block copolymer 310 such as polystyrene (PS)-poly (methyl-methacrylate) (PMMA) is formed on the template. Other block copolymers can be used for this application including but not limited to: polystyrene-b-polyisoprene, polystyrene-b-polybutadiene, polystyrene-b-poly vinylpyridine, polystyrene-b-polyethylene oxide, polystyrene-b-polyferrocyline or other combination of block copolymers based on conventional photoresists.

The PS-PMMA self-assembles into cylinders 312, 314 that can be subsequently removed by selective removal of the PMMA domain 312′, as illustrated in FIG. 3b. The openings can then be formed in the underlying template 320 by suitable techniques, such as reactive ion etching with a CHF₃ plasma and pattern transfer into the template, as illustrated in FIG. 3C. The template 320 can be formed of any suitable material, such as SiO₂. The nano-patterned template 320 is then used to selectively control the growth of nanostructures 330 onto the substrate 340, as illustrated in FIG. 3Dd. The growth technique may comprise any number of suitable techniques, such as molecular beam epitaxy (MBE) growth of heteroepitaxially-grown InAs quantum dots 330 with diameters about 20 nm or less. In the step illustrated in FIG. 3E, the template 320 is then removed by any suitable technique, such as wet etch HF chemistry.

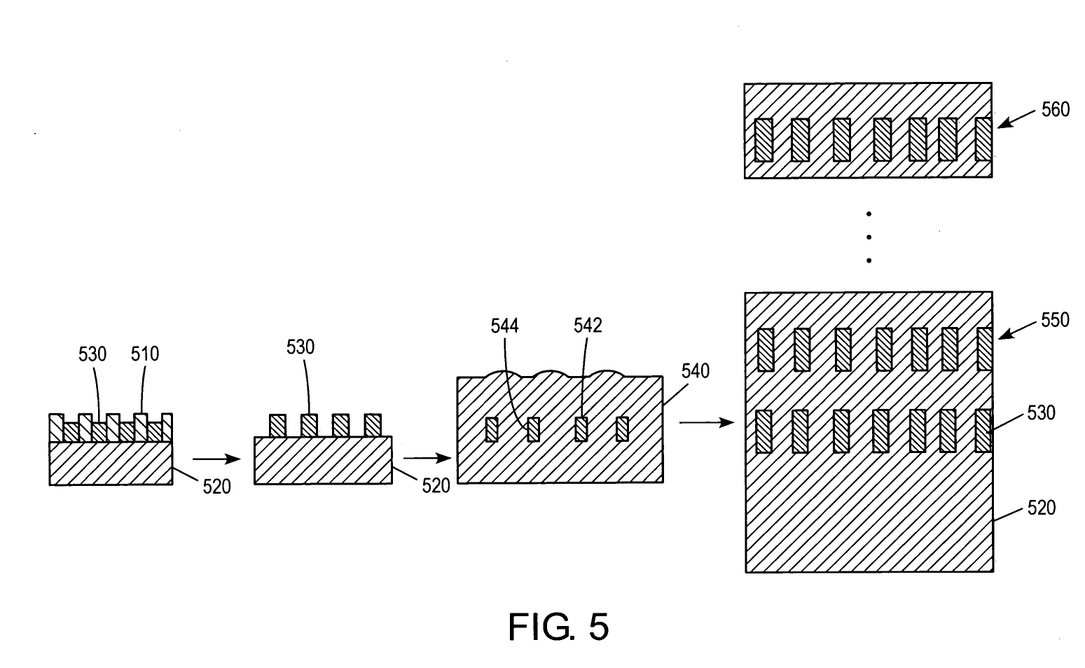

High resolution TEM images of template grown InAs quantum dots, where SiO₂ templates have been removed subsequent to growth, are shown in FIG. 4A-4B. The quantum dots illustrated in FIG. 4A-4B were grown under different time conditions. The nanostructure illustrated in FIG. 4A had a growth time of 387 seconds, while the nanostructure illustrated in FIG. 4B had a growth time of 774 seconds.

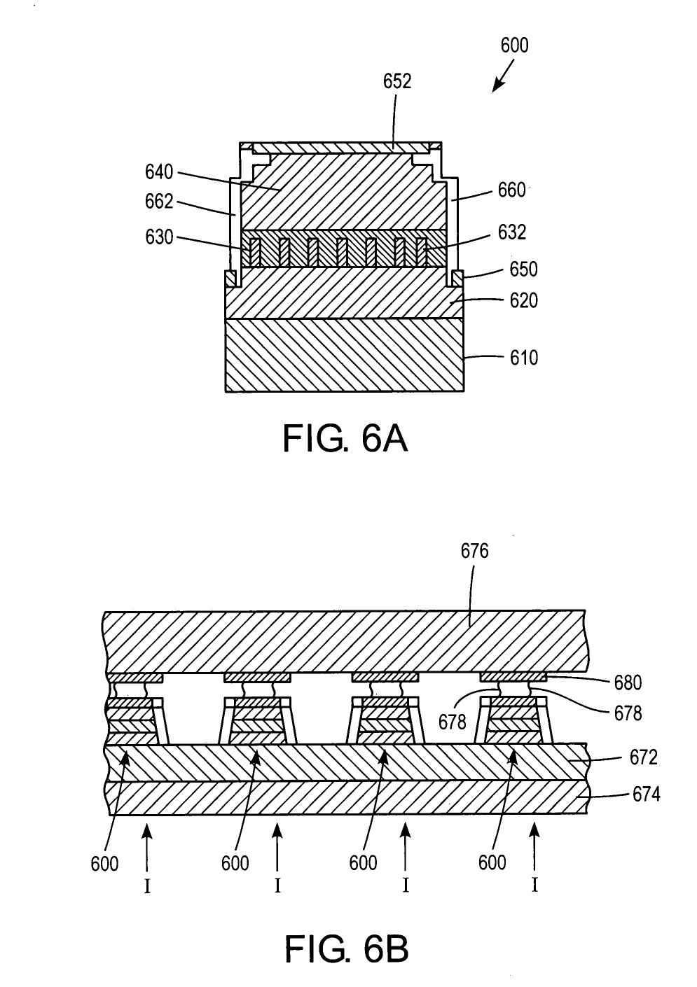

In one embodiment, the templated grown quantum dot array can be used as a seed layer for growth of consecutive dot layers. In this approach, subsequent to the templated growth of quantum dots, the template may be removed and the quantum dots, which can be formed from any suitable material such as InAs, and can be capped with a capping layer such as a GaAs or InGaAs layer, and next or subsequent layers of quantum dots are grown through conventional methods such as self-assembly Stranski-Krastanow. The templated grown quantum dots, which have uniform size and spacing, will dictate the nucleation sites of the Stranski-Krastanow growth quantum dots in the following layer(s). Thus, even if the second or subsequent layer of quantum dots are grown through Stranski-Krastanow processes, one may obtain a very high-density dot array with excellent dot-spacing control. This process is schematically shown in FIG. 5. As illustrated therein, a template 510 is formed according to previously described techniques and rests on a suitable substrate 520. An array of quantum dots 530 are grown in the openings of the template 510, as also previously described herein. Next, the template 510 can be removed by any suitable technique, such as dissolution with hydrofluoric acid. Optionally, oxides from the quantum dots 530 may then be removed by a suitable treatment of the type described above.

A capping layer 540 of any suitable material, such as GaAs can then be applied, which may cover the top surfaces 542, and optionally the lateral surfaces 544 of the quantum dots 530. The capping layer can be GaAs, according to one embodiment. The thickness of the GaAs capping layer has to be carefully chosen to allow for vertical dot coupling and thus density control. One or more additional layers 550, 560 may then be grown on top of the capped template-grown quantum dots 530. These additional layers 550, 560 need not be grown with a template, but rather can be grown by conventional self-assembly techniques, such as Stranski-Krastanow. The template growth quantum dots 530 act as a series of well-defined nucleation sties for the additional layer(s) 550, 560, thereby providing for improved density and regularity in the additional layers 550, 560 even though the quantum dots in these additional layers are not templated. Having a multi-layer stack of quantum dots may be a necessary condition for fabrication of high performance focal plane array (FPA) infrared (IR) detectors. Even with high density quantum dot layers it may be necessary to have multiple layers to absorb a high fraction of the incident light.

It should be noted that the use of a wetting layer to form the first template-grown array of quantum dots or nanostrucutres is optional, and thus may be omitted. However, most random self-assembly techniques, such as Stranski-Krastanow, utilize a wetting layer. Thus, the technique and structure illustrated in FIG. 5 may incorporate at least one wetting layer beneath the one or more additional layers 550, 560.

According to an optional embodiment, the templated growth approach can be used to grow nanostrucutres such as quantum dots that are substantially defect or dislocation free on low cost substrates, including silicon. The three-dimensional finite element model described in U.S. Pat. No. 7,122,827 by Alizadeh et al., the entire contents of which is incorporated by reference herein, can be used to predict and optimize the dimensions of the templated quantum dot geometry and dimensions for which substantially defect free structures are obtained. Use of substantially defect free, high optical quality templated growth nanostructures allows for the fabrication of high performance IR devices or detectors. Performance can be characterized in terms of high responsivity and detectivity. In addition, fabrication of such devices on low cost substrates such as silicon is highly desirable for the integration of optical and electronic read-out elements.

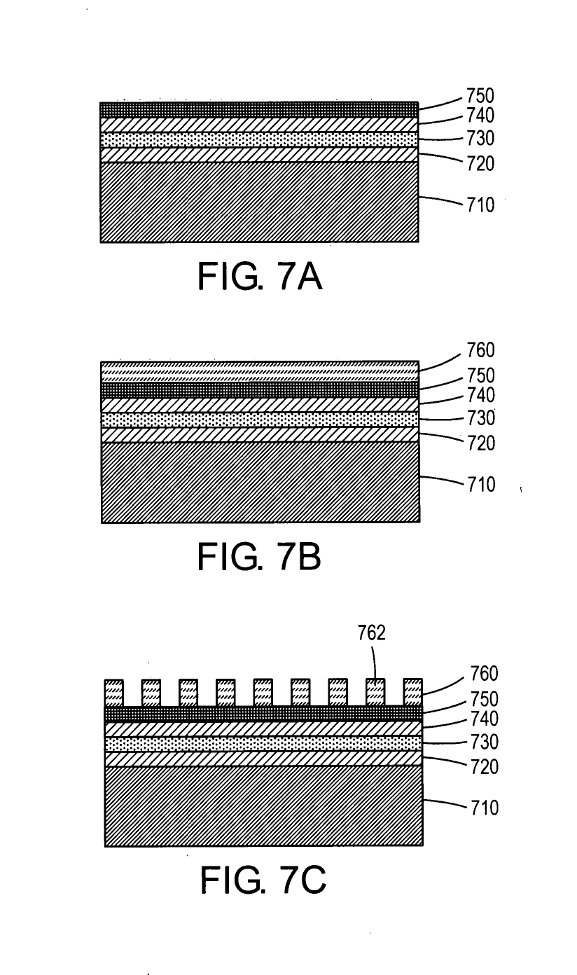

According to another embodiment of the present invention, a device 600 having contacts that are doped to form either a n-i-n or p-i-p photoconductor device can be provided, as illustrated in FIG. 6A. According to the illustrated embodiment the active layer or element 630 (“i-layer”) comprises a stack of nanostructures or quantum dots 632 formed as set forth according to any of the embodiments described herein. As illustrated in FIG. 6A, a substrate 610 may have a doped layer 620 disposed thereon. The substrate 610 may optionally be formed from silicon. The substrate 610 can itself be a multi-layer structure. The layer 620 can be formed from any suitable material, such as GaAs. The layer 620 can comprise either an n-doped layer, as in the case of a n-i-n device, or can comprise a p-doped layer, as in the case of a p-i-p device. The active layer 630 can likewise be formed of any suitable material. For example, the active layer 630 can comprise InAs quantum dots formed according to the principles of the present invention and described herein. The illustrated device further comprises a second doped layer 640 disposed on the active layer 630. The second doped layer 640 can also be formed from any suitable material, such as GaAs. The layer 640 can comprise an n-doped layer, as in the case of an n-i-n device, or can comprise a p-doped layer, as in the case of a p-i-p device. The quantum dots 632 can sit in or near layered structures such as quantum wells or barriers or other structures used, for example, to increase absorption, lower noise and, or lower stress. Such devices operate in a photoconductive mode, where a constant bias across the device is necessary. Additional doping within the quantum dots may also be desirable for a better matching of the Fermi level of quantum dots to the doped contacts. This in turn will improve the transport properties.

It is anticipated to operate the quantum dot based infrared detectors in a photoconductive mode. In quantum dot based infrared detectors, the 3-dimensionally confined quantum dots act as a pseudo dopant that can be ionized by the incident infrared light. Upon light absorption, the electrons may be excited to the conduction band of surrounding GaAs, while the holes will be trapped in the quantum dots. In these devices, there is a small probability for the hopping of holes but in general no large minority hole current is expected.

The n-i-n and p-i-p devices described above, can be used in either frontside or backside illumination configurations. Conventional procedures such as mesa etching and/or wafer thinning may be used to avoid undesired light absorption through the substrate. Metal contacts 650, 652 or passivation layers 660, 662 may optionally be present as well. This in turn will allow for the maximum light transmission through the active nanostructures region and yield a high performance device.

In the n-i-n and p-i-p devices described earlier, metal contacts 650, 652 such as Au, Ge, Pd, Pt or their alloys are used to form ohmic contacts with the top and bottom doped GaAs layers. In some devices, use of a thin metallic layer maybe contemplated to allow for light transmission through the device, especially in photodectors constructed for top-side illumination. Alternatively, contacts such as indium/tin/oxide (ITO) can be used to allow for infrared light transmission. Finally, metal contacts can be deposited in selective regions of the structure (through ring or mesa structures), while leaving large openings for direct light absorption.

The quantum dot based infrared n-i-n and p-i-p devices 600 described earlier may be used on either flat or curved/hemispherical surfaces. The quantum dot based infrared n-i-n and p-i-p devices described earlier may be used in conjunction with additional optical devices including but not limited to lenses, collectors, antennas, etc., to enhance light absorption, quantum efficiency and thus detectivity.

The quantum dot based infrared n-i-n and p-i-p devices 600 described above may be used as single element detectors or in a focal plane array configuration. A photodector 670 comprising an array of such devices 600 is illustrated in FIG. 6B. As illustrated therein, the photodetector 670 comprises an array of individual devices 600, each formed and constructed as described above. As indicated by the arrows I, the detector 670 is constructed to be back-side illuminated. This feature is of course optional, and the detector may be constructed for top-side, or an other illumination scheme. The devices 600 are disposed on a suitable material(s) acting as a base. According to the illustrated example, the devices are disposed on a two layer base. the first layer 672 can comprise a GaAs buffer layer, and the second layer 674 can comprise a GaAlAs layer that acts as an etch stop, or to otherwise protect the device in the event the original substrate is removed by etching, or another suitable technique The devices are in electrical communication with appropriate circuitry 676, that may be configured to read the emissions from the devices 600. The devices 600 may be connected in any suitable manner. According to the illustrated embodiment, the devices 600 are each connected to the circuitry 676 by leads 678 having one end attached the a contact (e.g., 652) of the device, and the other end connected to a contact pad 680.

Currently, quantum dot-based infrared photo detectors require multiple layers (currently reported from 10 to 70 layers) of quantum dots in order to maximize infrared light absorption. The template growth approach presented here can be used for fabrication of multiple layer quantum dots as shown in FIG. 5. It should be noted that the area density of dots (number of quantum dots per layer) during self-assembly according to the Starnski-Krastanov growth technique is in the order of 10⁸, and possibly up to about 10¹⁰ dots/cm². The template growth approach according to the present invention, particularly when using block copolymer lithography or anodized alumina templating, allows for area densities of up to at least 10¹² dots/cm². This large density of quantum dots within a given array is achieved through fabrication of very dense arrays of holes in the template. In the particular case of block copolymer lithography, this can be achieved by controlling the molecular weight and composition of the block copolymer. With a larger density of dots or fill factor, maximum light absorption within a given layer can be achieved. Therefore, the number of quantum dot layers in the IRPD device can be dramatically decreased without adversely impacting the light absorption properties. This approach is advantageous from both manufacturing and cost points of view.

Nanostructures or quantum dots obtained through self-assembly Stranski-Krastanov method are usually pyramidal shape where the base of a typical pyramid is 10-20 nm and its height is between 4-8 nm. The template growth approach presented here allows for fabrication of uniform arrays of nanostructures with selected dimensions, such as diameters and heights. This precise control over nanostructure dimensions enables control and improvement of light absorption and leakage current in the resulting device. The template growth approach proposed in this invention allows for the fabrication of substantially defect free nanostructures, such as quantum dots and nanowires of selected diameters and heights even during heteroepitaxial growth.

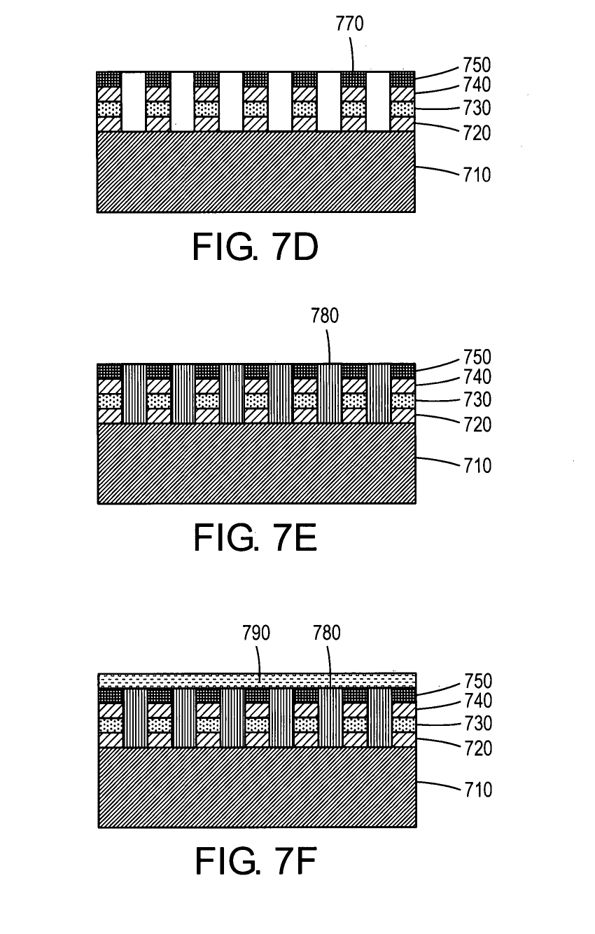

In FIG. 7A-7D, the main steps for the fabrication of sensitive photodetectors through an alternative nano-patterning and etching approach is shown. In this approach a substrate 710 formed of any suitable material, such as GaAs, InP, Si, or Ge is provided. A multilayer structure such as a quantum well or a super-lattice is grown through well-know epitaxial growth techniques on the substrate. An example of such multilayer structure is illustrated in FIG. 7A and comprises a GaAs layer 720, an InAs layer 730, another GaAs layer 740 and a AlGaAs layer 750. The growth rate and time and the thickness of each of these layers are carefully chosen such as that each of the layers in the final structures is very flat and does not present defects. Once the desired multilayer/superlattice structure is built, a metal or dielectric sacrificial layer 760 is deposited on top of the multilayer (FIG. 7B). Next, techniques such as the previously described block copolymer lithography, nano-imprint, etc. techniques, in combination with the appropriate pattern transfer techniques, are used to transfer pattern into the dielectric or metallic mask 760. This procedure is illustrated, for example, in FIG. 3A-3B. However, one may envision that the block copolymer has a composition such that upon completion of the lithography process columns 762 of the SiO₂ or metal are formed instead of holes, as in previously described embodiments (FIG. 7C). The arrays of nano-patterned SiO₂ or nano-patterned metal columns 762 can then be used a sacrificial mask for further etching of the multi-layer structure. Well-known reactive ion etching processes based on Cl chemistry can be used. As a result of etching we have produced nano-columns 770 of GaAs/InAs/GaAs/AlGaAs structures (FIG. 7D) with dimensions dictated by the dimensions of the openings/columns present in the sacrificial layer 760 which have a size on the order of that previously described herein. Further annealing and or passivation of this nanostructure array might be necessary to remove/heal any defects that can be generated during the etching process and thus improve the optical properties of these nanostructures.

The opening in the mask 760 can vary between about 5-100 nm in diameter or transverse dimension, and about 5-200 nm in height. Dimensions of the mask 760 should be such that the resulting nanostructures or quantum dots are highly confined, for example, smaller than the Bohr radius of the semiconductor (i.e., about 1-40 nm). Alternatively, the diameter or transverse dimension of the nanostructures were dots can be about 30 nm or less.

The etched nanostructured multi-layer construction described above can be used, for example, as the active part of n-i-n, p-i-n or p-i-n devices similar to the previously described template-grown quantum dots.

According to an additional alternative embodiment, the above-described etched multilayer nanostructure configuration (FIGS. 7A-7D) is backfilled and planarized using and infrared reflecting polymer 780 (FIG. 7E). Finally, the structure is coated with an anti-reflecting layer 790 (FIG. 7F).

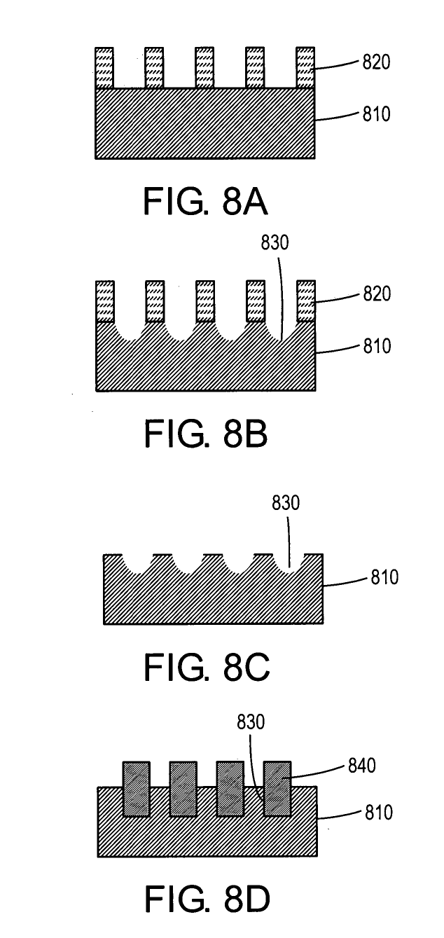

Nanostructures or quantum dots may also be formed in a controlled manner according to a further embodiment of the present invention which is illustrated, for example, in FIG. 8A-8D. As illustrated therein, a substrate 810 is provided formed of any of the previously described materials, GaAs being one such example. A patterned template 820 is provided on the substrate 810 (FIG. 8A). The template 820 is formed of any suitable material, as previously described herein. The template 820 is provided with the pattern by any of the previously described techniques, such as block copolymer lithography. The substrate 810 can then be selectively etched to produce etch pits 830 therein (FIG. 8B). The substrate 810 can be etched according to any suitable technique, such as those previously described herein. According to one exemplary technique, a mild wet etch solution comprising NH₄OH:H₂O=1:3 and is supplied to the exposed areas of the substrate 810 for approximately 20 seconds. After etching, the substrate 810 is dried via a baking step, which can be carried out in an MBE chamber. Next, the template 820 is removed by any suitable technique such as those previously described herein. It should be noted that although the etch pits 830 which are illustrated have a somewhat rounded bottom, the present invention should not be construed as being limited at this particular geometry etch pit. To the contrary, the number of different geometrical configurations can be formed in the substrate 810. Next, the template 820 is removed according to any suitable technique, such as those previously described herein (FIG. 8C). Then, nanostructures or quantum dots 840 are grown in the etch pits 830 according to any suitable previously-described technique, such as MBE. The nanostructures or quantum dots 840 can be formed from any suitable material, such as any of the semiconductor materials described above. By way of non-limiting example, the nanostructures or quantum dots 840 can comprise InAs. Thus, according to the above described technique, the nanostructures or quantum dots 840 are produced in an array which is dictated by the openings formed in the template 820. Like the previously described embodiments, this technique provides certain advantages, including the ability to control the dimensions of the nanostructures or quantum dots 840, producing a denser array, and avoiding reliance on a wedding layer to grow the nanostructures or quantum dots 840 on the substrate 810.

The opening in the template 820 can vary between about 5-20 nm in diameter or transverse dimension, and about 5-200 nm in height. Dimensions of the template 820 should be such that the resulting nanostructures or quantum dots are highly confined, for example, smaller than the Bohr radius of the semiconductor (i.e., about 1-40 nm). Alternatively, the diameter or transverse dimension of the nanostructures or dots can be about 30 nm or less.

In addition to advantages in cost and manufacturability, the nano-patterning approaches presented herein are flexible in that they can be used for direct growth through metal/dielectric masks formed through pattern transfer, or through pattern reversal, allowing for quantum dot formation through etching. The latter has been demonstrated for e-beam patterned structures. The block copolymer or nano-imprint templates yield smaller structures than e-beam patterning over significantly larger areas thereby allowing for size scales where quantum dot behavior can be obtained. This flexibility is important as the performance of the dots depends critically on the two electron energy levels formed in the structure. The energy difference between the two levels, as well as the difference between the top level and continuum, will significantly impact device performance. The values depend on size, and doping level. It may be possible that better characteristics can be obtained via one technique vs. another; one would expect better doping control with whole-wafer growth and post-patterning through etch. Further, standard chemical etch recipes exist for nearly all III-V and II-VI semiconductors for removal of the plasma-damaged etch layer, and surface passivation. As the dimensions of the dots are small, surface to volume ratios are extreme and surface recombination effect may become very important. On the other hand, in the absence of thermalization processes, the transferred incident photon energy may be sufficient to overcome trap states.

All numbers expressing quantities or parameters used in the specification are to be understood as being modified in all instances by the term “about”. Notwithstanding that the numerical ranges and parameters set forth, the broad scope of the subject matter presented herein are approximations, the numerical values set forth are indicated as precisely as possible. For example, any numerical quantification may inherently contains certain errors resulting from the standard deviation indicative of inaccuracies in their respective measurement techniques.

Although the present invention has been described in connection with preferred embodiments thereof, it will be appreciated by those skilled in the art that additions, deletions, modifications, and substitutions not specifically described may be made without departure from the spirit and scope of the invention as defined in the appended claims.

We claim:

1. A method of forming a photodetector comprising:
providing a substrate;
providing a template having an opening with its largest dimension no greater than about 100 nm, the opening defining a confined space, and locating the template over the substrate; and
growing the semiconductor nanostructure within the confined space defined by the opening in the template.

2. The method of claim 1, wherein the semiconductor nanostructure comprises one or more of a quantum dot, nanowire, Type-II super lattice, quantum well, quantum barrier; tunnel barrier structure, substrate re-growth, or graded layer.

3. The method of claim 1, wherein the substrate comprises at least one of: GaAs, InP, Si, or Ge.

4. The method of claim 1, wherein the template comprises at least one of: Si₃N₄, SiON, SiBON, Al₂O₃, or NbOₓ.

5. The method of claim 1, wherein the opening in the template is formed by: block copolymer lithography, nano-imprinting, e-beam lithography, UV lithography, interference lithography, soft lithography, anodized alumina templating, or two-dimensional colloidal crystal lithography.

6. The method of claim 5, wherein the largest transverse dimension of the opening is about 1-40 nm.

7. The method of claim 5, wherein the largest dimension of the opening in the template is no greater than about 20 nm.

8. The method of claim 7, wherein the largest transverse dimension of the opening in the template is about 5-20 nm.

9. In the method of claim 8, wherein the opening has a height of about 5-200 nm.

10. The method of claim 1, wherein the semiconductor nanostructure is grown by: molecular beam epitaxy, metal organic chemical vapor deposition, laser ablation, atomic layer deposition, liquid phase epitaxy, high-pressure temperature gradient recrystallization, high-pressure solution growth, sublimation, electrochemical deposition, or combinations thereof.

11. The method of claim 1, wherein the semiconductor material comprises a Group III/V, II/VI, V, or alloy thereof.

12. The method of claim 10, wherein the semiconductor material comprises InAlGaAs or InAs.

13. The method of claim 1, wherein dopant atoms are introduced during growth of the semiconductor nanostructure.

14. The method of claim 1, wherein the template comprises a plurality of openings, and a corresponding plurality semiconductor nanostructures are grown therein resulting in an array of semiconductor nanostructures disposed over the substrate.

15. The method of claim 13, wherein the array of semiconductor nanostructures has a density greater than about 10¹⁰ nanostrucutres/cm².

16. The method of claim 15, wherein the density is at least 10¹² nanostrucutres/cm².

17. The method of claim 1, further comprising:
forming a capping layer on the semiconductor nanostructure.

18. The method of claim 17, wherein the capping layer contacts at the least a top surface of the semiconductor nanostructure.

19. The method of claim 18, wherein the capping layer additionally contacts lateral surfaces of the semiconductor nanostructure.

20. The method of claim 17, wherein the capping layer comprises GaAs.

21. The method of claim 1, further comprising:
removing the template after growing the semiconductor nanostructure.

22. The method of claim 21, wherein the template is removed by wet and/or dry chemical etching.

23. The method of claim 22, wherein the template is removed by exposing the template to hydrofluoric acid.

24. The method of claim 1, further comprising:
exposing the template is to cleaning process comprising wet chemical etching, high temperature exposure under controlled gas flow, low temperature exposure in conjunction with atomic H₂ plasma, or combinations thereof, prior to growing the semiconductor nanostructure.

25. The method of claim 24, further comprising:
depositing and epitaxial buffer layer onto the substrate subsequent to the cleaning process.

26. The method of claim 25, wherein the buffer layer comprises GaAs or InGaAs.

27. The method of claim 1, further comprising: applying a capping layer comprising a higher band semiconductor material to the semiconductor nanostructure.

28. The method of claim 1, wherein the opening in the template is formed by depositing a layer of block copolymer on the template which self-assembles into first and second domains, selectively removing one of the first or second domains thereby leaving a void in layer of block copolymer, and selectively removing an area of the template corresponding to the void, thereby forming the opening.

29. The method of claim 28, wherein the block copolymer comprises: polystyrene-poly(methyl-methacrylate); polystyrene-b-polyisoprene; polystyrene-b-polybutadiene; polystyrene-b-poly vinylpyridine; polystyrene-b-polyethylene oxide; or polystyrene-b-polyferrocyline.

30. The method of claim 17, further comprising:
growing at least one additional layer comprising at least one additional semiconductor nanostructure on top of the capped semiconductor nanostructure, wherein the least one additional semiconductor nanostructure is grown by a self-assembly technique.

31. The method of claim 30, wherein the self-assembly technique comprises a Stranski-Krastanow technique.

32. The method of claim 1, further comprising:
annealing the semiconductor nanostrucuture.

33. A method of forming a photodetector, the method comprising:
providing a substrate;
forming a multilayer semiconductor structure on the substrate;
providing a template having an opening with its largest dimension no greater than about 100 nm, and locating the template over the multilayer semiconductor structure;
selectively removing a portion of the multilayer semiconductor structure corresponding to the opening; and
removing the template.

34. The method of claim 33, wherein the template comprises a plurality of openings, and a corresponding plurality of portions of the multilayer semiconductor structure are selectively removed forming a plurality of voids, resulting in an array of discrete multilayer semiconductor structures on the substrate.

35. The method of claim 34, wherein the multilayer semiconductor structure comprises a first layer of GaAs, a second layer of InAs, a third layer of GaAs, and a fourth layer of AlGaAs.

36. A method of forming a photodetector, the method comprising:
providing a substrate;
providing a template having an opening with its largest dimension no greater than about 100 nm, and locating the template over the substrate;
selectively removing a portion of the substrate corresponding to the opening thereby forming an etch pit;
removing the template; and
growing a semiconductor nanostructure in the etch pit.

37. The method of claim 36, wherein the template comprises a plurality of openings, and a corresponding plurality of portions of the substrate are selectively removed forming a plurality of etch pits, and growing a semiconductor nanostructure and each of the etch pits resulting in an array of discrete semiconductor nanostructures on the substrate.

38. The method of claim 37, wherein the substrate comprises GaAs and the semiconductor nanostructures comprise InAs.

39. A photodetector comprising:
a substrate;
a first layer comprising an n-doped or p-doped material disposed on the substrate;
an active layer disposed on the first layer comprising an array of semiconductor nanostructures having a density greater than about 10¹⁰ nanostrucutres/cm²; and
a second layer disposed on the active layer comprising an n-doped or p-doped material.

40. The photodetector of claim 39, wherein the density is at least about 10¹² nanostrucutres/cm².

41. The photodetector of claim 39, further comprising a first contact and electrical communication with the first layer, and a second contact in electrical communication with the second layer.

42. The photodetector of claim 39, wherein the first layer comprises an n-doped layer, and the second layer comprises an n-doped layer.

43. The photodetector of claim 39, wherein the first layer comprises a p-doped layer, and the second layer comprises a p-doped layer.

44. The photodetector of claim 39, wherein the first and second layers comprises a doped GaAs material, and the semiconductor nanostructures comprise InAs.

45. A device comprising a plurality of the photodetectors of claim 39 configured in an array, each photodetector in electrical communication with a read-out circuit.

46. A photodetector comprising:
a substrate; and
an array of semiconductor nanostructures disposed over the substrate, each of the semiconductor nanostructures having a transverse dimension no greater than 20 nm, and the array having a density of at least about 10¹⁰ nanostrucutres/cm².

47. The photodetector of claim 46, wherein the density is at least about 10¹² nanostrucutres/cm².

48. The photodetector of claim 46, wherein the semiconductor nanostructures are isolated from one another.

49. The photodetector of claim 46, further comprising a layer of material between the substrate and the semiconductor nanostrucutures, whereby the semiconductor nanostructures are connected via the layer.

50. The photodetector of claim 46, wherein the substrate comprises at least one of GaAs, InP, Si, or Ge.

51. The photodetector of claim 50, wherein the substrate comprises Si.

52. The photodetector of claim 46, wherein the semiconductor nanostructure comprises one or more of a quantum dot, nanowire, Type-II super lattice, quantum well, quantum barrier; tunnel barrier structure, substrate re-growth, or graded layer.

53. The photodetector of claim 46, wherein the semiconductor material comprises a Group III/V, II/VI, V, or alloy thereof.

54. The photodetector of claim 46, wherein the semiconductor material comprises InAlGaAs or InAs.

55. A device comprising a plurality of the photodetectors of claim 46 configured in an array, each photodetector in electrical communication with a read-out circuit.
